(19) United States
(12) Patent Application Publication
(10) Pub. No.: US 2026/0255038 A1
(43) Pub. Date: Aug. 27, 2026

(54) ON-BOARD CAMERA DEVICE

(71) Applicant: Faurecia Clarion Electronics Co., Ltd., Saitama-shi (JP)

(72) Inventors: Takayuki NEGISHI, Saitama (JP); Keisuke TSUKIASHI, Saitama (JP)

(73) Assignee: Faurecia Clarion Electronics Co., Ltd., Saitama-shi (JP)

(21) Appl. No.: 19/549,679

(22) Filed: Feb. 25, 2026

(30) Foreign Application Priority Data
Feb. 27, 2025 (JP) 2025-029946

(51) Int. Cl. H04N 23/54; H05K 1/02; H05K 1/14

(52) U.S. Cl. CPC H04N 23/54; H05K 1/0215; H05K 1/147; H05K 2201/09027; H05K 2201/09063

(57) ABSTRACT

An on-board camera device includes a rigid printed circuit board (PCB) having a first conductive portion configured to supply a prescribed power potential and a first opening passing through the rigid PCB, and a flexible printed circuit board (FPCB) having a second opening passing through the FPCB and a second conductive portion positioned opposite the first conductive portion and shaped to conform to the second opening. A housing includes securing portions that extend through the first opening and the second opening to fasten the rigid PCB to the FPCB while urging the first conductive portion into electrical contact with the second conductive portion, thereby providing electrical connection without enlarged external terminals and enabling a smaller overall device and simplified assembly. The securing portions may be protrusions extending from the housing, or a structure including a third opening formed in the housing and a mating protrusion engaged with the third opening.

### TECHNICAL FIELD

The present invention relates to an on-board camera device in which terminals of a flexible printed circuit board (hereinafter also abbreviated as FPC) are electrically connected to a built-in rigid printed circuit board (hereinafter also abbreviated as board).

### CONVENTIONAL TECHNOLOGY

For example, when a camera device is used in an environment where the outside temperature is low, a heater may be provided around the lens barrel to make the image through the lens less susceptible to the effects of the outside temperature. Generally, a connector is often used as a terminal for electrically connecting the heater to a board on the camera device side (see, for example, Patent Document 1, Patent Document 2, and Patent Document 3).

### PRIOR ART DOCUMENTS

### Patent Documents

Patent Document 1: Japanese Unexamined Utility Model Application Publication H5-36872

Patent Document 2: U.S. Patent Application Publication No. 2005/0230813

Patent Document 2: U.S. Patent Application Publication No. 2019/0027842

### SUMMARY OF THE INVENTION

### Problem to be Solved by the Invention

However, in the techniques disclosed in the patent documents, using a connector as a terminal for electrically connecting the board on the camera device side not only increases the structural size but also may increase difficulty in assembling the camera device.

An object of the present invention is to appropriately reduce the size of the on-board camera device as a whole by reducing the size of the terminals connected from the outside to the built-in board.

### Means for Solving the Problem

The present invention is an on-board camera device including:

a housing that forms an internal space;

a rigid printed circuit board provided in the housing and having prescribed rigidity; and

a flexible printed circuit board that supplies electric power from the rigid printed circuit board positioned in the housing to an electronic component positioned outside the housing,

wherein

the rigid printed circuit board includes:

a first conductive part that supplies a prescribed electric potential serving as a power supply; and

a first opening part that penetrates the rigid printed circuit board,

the flexible printed circuit board includes:

a second opening that penetrates the flexible printed circuit board; and

a second conductive part that is positioned at a position facing the first conductive part of the rigid printed circuit board and has a shape along the second opening part,

the housing includes:

a securing part that is inserted into the first opening part and the second opening part and secures the rigid printed circuit board to the flexible printed circuit board while bringing the first conductive part into contact with the second conductive part; and

the securing part is a protrusion extending from the housing or a third opening part provided on the housing and a protrusion that is mated with the third opening part.

### EFFECT OF THE INVENTION

According to the present invention, the terminals connected to the built-in board from the outside can be reduced in size, thereby enabling reduction in overall size of the on-board camera device. The following description of the embodiments will elucidate the problems, configurations, and effects other than those described above.

### BRIEF DESCRIPTION OF THE DRAWINGS

[FIG. 1] An exploded perspective view depicting an example of a configuration of a camera device as an example of an on-board camera device according to Embodiment 1.

FIG. 2 A partial cross sectional view depicting an example of a configuration of a camera device main body to which a heater depicted in FIG. 1 is equipped.

FIG. 3 A plan view depicting an example of a configuration of a front case where a board depicted in FIG. 2 is stowed.

FIG. 4 A plan view depicting an example of a configuration of a surface of an FPC facing the board.

FIG. 5 A plan view depicting an example of a configuration of a surface of the FPC facing the front case.

FIG. 6 A cross-sectional view depicting an example of a configuration in which the FPC is secured by a securing part between the front case and the board.

FIG. 7 A plan view depicting an example of a configuration of an FPC of a camera device according to Embodiment 2.

FIG. 8 A plan view depicting an example of a configuration of an FPC of a camera device according to Embodiment 3.

FIG. 9 A plan view depicting an example of a configuration of a surface of an FPC in a camera device according to Embodiment 4 that faces a board.

FIG. 10 A plan view depicting an example of the configuration of the surface of the FPC of the camera device according to Embodiment 4 that faces the front case.

FIG. 11 A cross-sectional view depicting an example of a configuration in which the FPC is secured between the front case and the board by two securing parts.

FIG. 12 A plan view depicting an example of a configuration in which the FPC is positioned and arranged on an upper surface of the board.

FIG. 13 A partial cross-sectional view depicting a modified example of a configuration in which a securing part secures a flexible printed circuit board to the front case by clamping the flexible printed circuit board between the board and the front case.

FIG. 14 A partial cross-sectional view depicting a modified example of a configuration in which a securing part secures a flexible printed circuit board to the front case by clamping the flexible printed circuit board between the board and the front case.

### EMBODIMENTS OF THE INVENTION

An embodiment of the present invention is described below with reference to the figures.

### Embodiment 1

FIG. 1 is an exploded perspective view depicting an example of the configuration of camera devices 100, 100A, 100B, 100C, and 100D as examples of on-board camera devices according to Embodiment 1. In the depicted example, a camera device main body 1, heater 101, and cover 102 are depicted as disassembled along the optical axis 3C of the camera device main body 1. In the present embodiment, a camera device will be exemplified as the on-board camera device below. The on-board camera device is not limited to a camera device but may be any other device mounted on a vehicle.

In the following embodiments and specific examples, the horizontal direction HR57 and the vertical direction VT57 depicted in each drawing will be referred to. In the following embodiments, a surface facing upward in the vertical direction VT57 may be expressed as an upper surface, and a surface facing downward in the vertical direction VT57 may be expressed as a lower surface.

Furthermore, in the following embodiments and specific examples, the terms "form" and "provide" include a case where a member is integrally formed, and a case where members are formed separately and then adhered or welded. In the following embodiments and specific examples, the inside refers to the closed space side formed by mating a front case 5 and a rear case 7 together. The description "outside" refers to a side that is not included in the space and is a released open space side.

A camera device main body 1 includes, in terms of external appearance, a conductive lens barrel 3, a conductive front case 5, a conductive rear case 7, and a mounting connector 9. The front case 5 is mated with the rear case 7 to form an internal space and to form a substantially rectangular parallelepiped in external appearance. In the present embodiment, at least a first of the front case 5 and the rear case 7 is also referred to as a "housing".

A camera device 100 is an example of an on-board camera device. The camera device 100 includes a housing that forms an internal space, a rigid printed circuit board (hereinafter referred to as board) 4 that is provided in the housing and has a prescribed rigidity, and a flexible printed circuit board (hereinafter also abbreviated as FPC) 112 that is flexible, for example, and that supplies power from the rigid printed board 4 positioned inside the housings 5 and 7 to electronic components positioned outside the housing. The outside of the housing is outside the space formed by the housing.

Of the four corners on the upper surface of the front case 5, two corners located diagonally opposite each other are formed with screw hole 5X into which screw 103A is screwed, and also with screw hole 5Y into which screw 103B is screwed. The lens barrel 3, the front case 5, the rear case 7, and the mounting connector 9 will be described in detail later.

The heater 101 includes a heat generating part 101A, a first descending part 101B, a horizontal part 101C, a second descending part 101D, and an FPC 112. The heat generating part 101A, the first descending part 101B, the horizontal part 101C and the second descending part 101D are configured as a continuous, integrated body. Two wires are provided inside the first descending part 101B, the horizontal part 101C, and the second descending part 101D. The first descending part 101B, the horizontal part 101C, and the second descending part 101D may be integral with the FPC 112.

The heat generating part 101A has a cylindrical shape. The heat generating part 101A is attached so as to surround the cylindrical lens barrel part 3Z of lens barrel 3 from the outside. The first descending part 101B is a member extending from the lower end of the heat generating part 101A along the vertical direction VT57.

The horizontal part 101C is a member extending in the horizontal direction HR57 from the end part of the first descending part 101B opposite to the end part of the heat generating part 101A. The second descending part 103D is a member extending in the vertical direction VT57 from the end part of the horizontal part 101C opposite to the end part of the first descending part 101B.

The FPC 112 is, for example, a flexible member extending along the horizontal direction HR57 so as to be continuous with the first descending part 101B. The FPC 112 is electrically connected to the heat generating part 101A via the two wires inside the first descending part 101B, the horizontal part 101C, and the second descending part 101D. The FPC 112 will be described below in detail.

The cover 102 is an exterior member that can be attached to the camera device main body 1, on which the heater 101 is attached, so as to cover the camera device main body 1 along the optical axis 3C that is aligned with the vertical direction VT57. When the cover 102 is attached to the camera device main body 1, the cover is fastened using screws 103A and 103B.

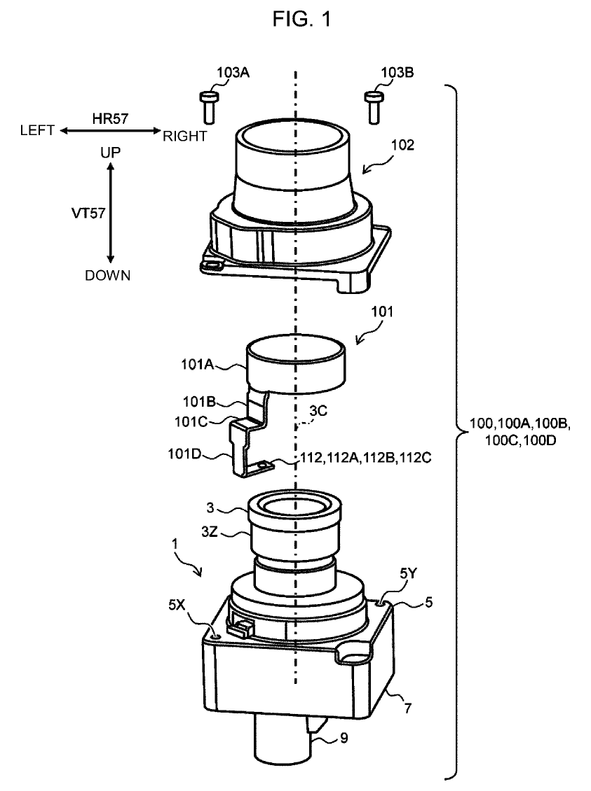

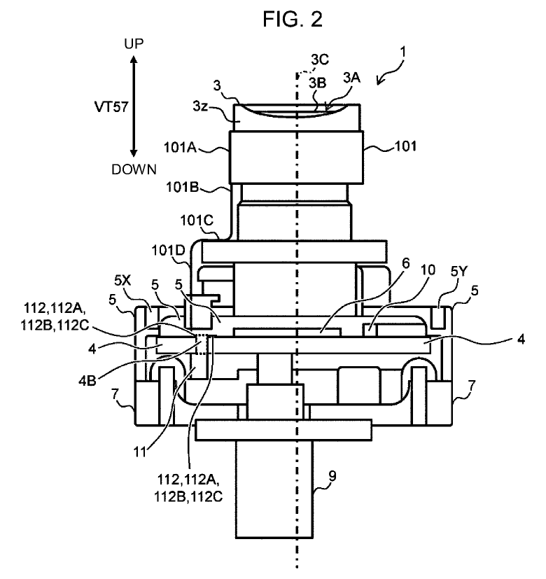

FIG. 2 is a partial cross sectional view depicting an example of a configuration of a camera device main body 1 equipped with the heater 101 depicted in FIG. 1. In FIG. 2, the cover 102 and the screws 103A and 103B are omitted from the depiction. In the depicted examples, hatching of the cross-sectional structure may be omitted.

The camera device main body 1 mainly includes a front case 5, a rear case 7, and a conductive mounting connector 9. The camera device main body 1 can be used in different orientations depending on the application by attaching the mounting connector 9 to an object.

When the lens barrel 3 is disposed in the depicted orientation, the lens barrel is located at the top of the camera device main body 1. The lens barrel 3 is formed, for example, in the form of a plurality of cylinders connected together, each having a different radius, with the radius of an upper cylinder being larger than that of a lower cylinder. The lens barrel 3 incorporates a lens 3A in an upper part thereof. The lens barrel 3 has a convex lens surface 3B of the lens 3A exposed on the upper surface.

The front case 5 is formed in, for example, a hollow quadrangular prism shape. The four corners on the upper surface of the front case 5 are rounded. A screw hole 5X into which the lower cylinder of the aforementioned lens barrel 3 can be inserted is formed in the front case 5. The lens barrel 3 described above is configured to be detachable from the front case 5 by screwing the lower cylinder into the screw hole 5X of the front case 5.

The rear case 7 is formed in, for example, a hollow quadrangular prism shape. Four corners of the lower surface of the rear case 7 are rounded. The rear case 7 is fitted to the front case 5 described above. The rear case 7 is fitted to the front case 5, whereby a space is formed inside the rear case 7 and the front case 5. A peripheral edge of the rear case 7 is a peripheral edge of an end part including an end part of the rear case 7. A peripheral edge of the front case 5 is a periphery of an end part including an end part of the front case 5.

The width of the front case 5 in a direction perpendicular to the direction parallel to the optical axis 3C of the lens 3A, that is, in the horizontal direction HR57, is formed to be substantially the same as the width of the rear case 7.

A mounting connector 9 connectable to a connector (not depicted) is provided on the lower surface of the rear case 7 so as to extend in a direction parallel to the optical axis 3C of the lens 3A.

First, an outline of the configuration of the camera device main body 1 according to the present embodiment will be described. The camera device main body 1 is made of a conductive material and includes the front case 5 and the rear case 7 that form a housing enclosing a rigid printed circuit board 4, and the lens barrel 3 that is also made of a conductive material. The front case 5 and the rear case 7 may be simply referred to as housing when not distinguished from each other. The camera device main body 1 includes, for example, the lens 3A supported by the lens barrel 3. An example of the configuration of the camera device main body 1 will be described in more detail below.

When the periphery of the front case 5 is mated to the peripheral edge of the rear case 7, an internal space is formed by the front case 5 and the rear case 7. The peripheral edge of the front case 5 is fixed to the peripheral edge of the rear case 7 by the adhesive applied between the peripheral edge of the front case 5 and the peripheral edge of the rear case 7. The adhesive also functions as a sealing material for sealing the closed space formed by the front case 5 and the rear case 7. The adhesive may be partially or completely hardened by UV radiation. If active alignment, which will be described later, is performed before hardening, the optical axis 3C of the lens 3A is positioned at an image sensor 6, which will be described later.

The board 4 is stowed inside the rear case 7. The image sensor 6 is provided on the board 4 near the intersection with an extension of the optical axis 3C of the lens 3A of the lens barrel 3 provided in the front case 5, for example. A hole to which the mounting connector 9 is mounted is provided in the lower surface of the rear case 7. The mounting connector 9 and a drive device 10 are provided on the lower surface of the board 4.

The connector 8 ensures electrical conduction between the mounting connector 9 and the board 4 by being fitted to the mounting connector 9. The drive device 10 includes an electronic circuit that drives the image sensor 6.

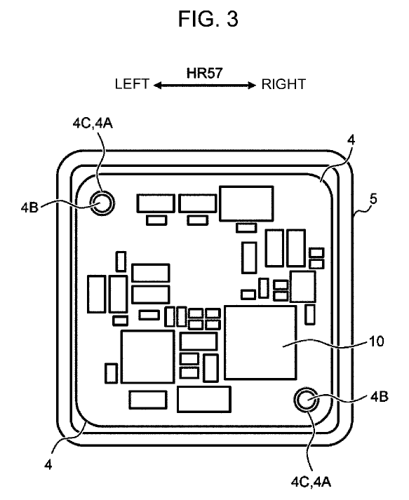

FIG. 3 is a plan view depicting an example of the configuration of the front case 5 where the board 4 depicted in FIG. 2 is stowed. In the depicted example, the rear case 7 depicted in FIG. 3 is depicted detached from the front case 5. FIG. 2 depicts the lower surface of the board 4, that is, the surface facing downward in the vertical direction VT57. The board 4 is, for example, rectangular, and four corners thereof are rounded. In the depicted example, a drive device 10 is mounted on the surface of the board 4, but the image sensor 6, for example, is not depicted.

The board 4 has one or more opening parts 4B formed therein. A first grounding part 4C and a first conductive part 4A, which will be described later, may be formed around the opening parts 4B. For example, the opening parts 4B are formed at two diagonal corners of the four corners of the board 4, respectively. A plurality of opening parts 4B can be provided in accordance with a second opening part 12A. For example, when an isolation insulating part 12Z described below branches in a first direction and a second direction, an opening part 4B is formed at a position that corresponds to one second opening part 12A positioned in the first direction and another second opening part 12A located in the second direction. By inserting each securing part 11 into one or more opening parts 4B, the board 4 is secured to a rear case 7 as an example of a housing.

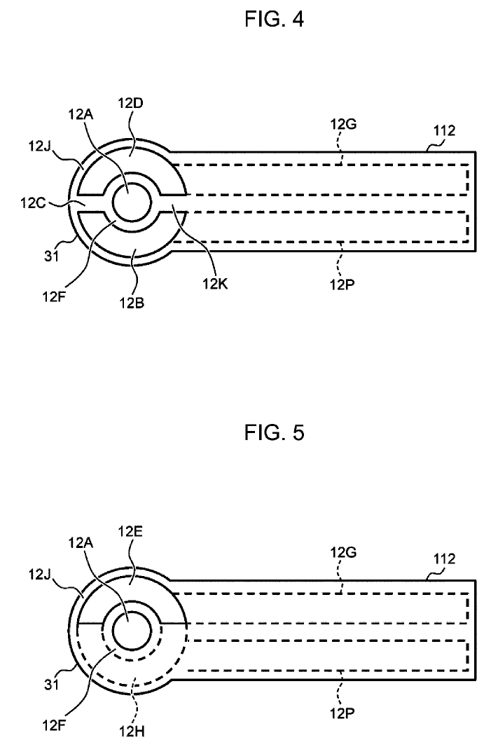

FIG. 4 and FIG. 5 are plan views depicting specific examples of the configuration of the FPC 112. FIG. 4 depicts an example of the configuration of the surface of the FPC 112 facing the board 4 (hereinafter also referred to as the lower surface). FIG. 5 depicts an example of the configuration of the surface of the FPC 112 that faces the front case 5 (hereinafter also referred to as the upper surface). That is, the upper surface depicted in FIG. 5 is the surface opposite to the lower surface depicted in FIG. 4.

The board 4 includes a first conductive part 4A that is a power supply and supplies a prescribed electric potential, and a first opening part 4B that penetrates the board 4. The FPC 112 includes a second opening part 12A that penetrates the FPC 112, and a second conductive part 12B that is positioned opposite the first conductive part 4A of the board 4 and has a shape that conforms to the second opening part 12A. The housing has a securing part 11 that is inserted into the first opening part 4B and the second opening part 12A to secure the board 4 to the FPC 112 while bringing the first conductive part 4A into contact with the second conductive part 12B, which is conductive. The securing part 11 is a protrusion extending from the housing. The securing part 11 will be described in detail later.

The FPC 112 has a configuration in which a ground wire 12G and a power supply [wire] 12P for ensuring electrical conduction with the heater 101 are wrapped in an insulator. That is, the wire 12G is grounded to ground potential. The wire 12P is connected to a power supply. The FPC 112 has an annular end part 31 on the side opposite to the end part connected to the heater 101.

As depicted in particular in FIG. 4, the front side of the annular end part 31 has a circular second opening part 12A, a peripheral edge insulating part 12F, a second grounding part 12D, a second conductive part 12B, an isolation insulating part 12C, an insulating part 12K, and an insulating part 12J. The second opening part 12A is a circular hole formed in the center of the annular end part 31. An annular peripheral edge insulating part 12F is formed around the second opening part 12A.

The second conductive part 12B has a semicircular arc shape with a radius larger than the radius of the second opening part 12A. The second grounding part 12D is a semicircular arc-shaped conductive member that has the same radius as the second conductive part 12B and shares a common center with the semicircular arc shape of the second conductive part 12B.

The second grounding part 12D is formed in an approximately half-circumference annular part of the periphery of the annular peripheral edge insulating part 12F. The second grounding part 12D is connected to the wire 12G. The second conductive part 12B is configured in an approximately half-circumference annular part of the periphery of the annular peripheral edge insulating part 12F. The second conductive part 12B is connected to the wire 12P. An annular insulating part 12J is formed around the second grounding part 12D.

The isolation insulating part 12C and insulating part 12K are formed between both ends of the approximately half-circumference annular part of the second grounding part 12D and both ends of the approximately half-circumference annular part of the second conductive part 12B. More specifically, the isolation insulating part 12C is formed between a first end of the approximately half-circumference annular part of the second grounding part 12D and a first end of the approximately half-circumference annular part of the second conductive part 12B. An insulating part 12K is formed between a first end of the approximately half-circumference annular part of the second grounding part 12D and a first end of the approximately half-circumference annular part of the second conductive part 12B.

The FPC 112 includes a peripheral edge insulating part 12F positioned along the peripheral edge of the second opening part 12A. The second conductive part 12B is positioned a prescribed distance away from the peripheral edge insulating part 12F.

The board 4 further includes a conductive first grounding part 4C that is grounded to a ground potential that is an electric potential relatively lower than the prescribed potential. The FPC 112 further includes the second grounding part 12D positioned at a position corresponding to the first grounding part 4C of the board 4. The second grounding part 12D is positioned along the second opening part 12A on the same surface as the second conductive part 12B. The isolation insulating part 12C is positioned between the second grounding part 12D and the second conductive part 12B.

As depicted in FIG. 5, the back side of the annular end part 31 includes a third grounding part 12E and an insulating part 12H. The third grounding part 12E is a conductive member formed in an approximately half-circumference annular part along the periphery of the annular peripheral edge insulating part 12F. The third grounding part 12E is connected to the wire 12G.

The FPC 112 includes a third grounding part 12E, which is grounded to the ground electric potential, on the back side of the surface on which the second grounding part 12D is positioned. The third grounding part 12E is positioned along the second opening part 12A.

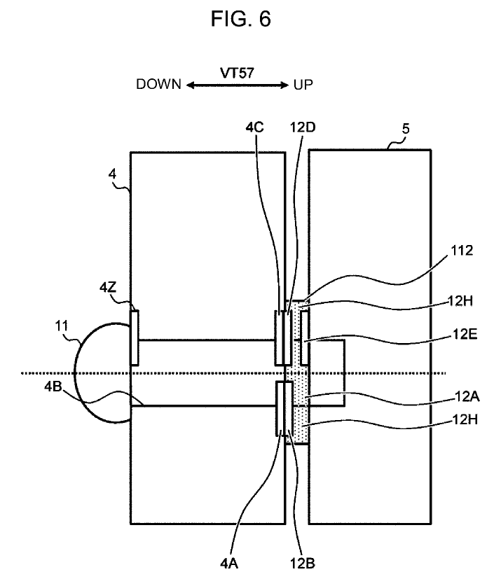

FIG. 6 is a cross-sectional view depicting an example of a configuration in which the FPC 112 is secured by the securing part 11 between the front case 5 and the board 4. In FIG. 6, hatching that should be depicted in the cross-sectional structure is omitted. In the following, the securing part 11 is, for example, a rod-shaped rivet that is inserted into a hole by being pushed in. The rivet may be part of the housing.

The FPC 112 is clamped between the front case 5 and the board 4, and is secured between the front case 5 and the board 4 by inserting the securing part 11, which is inserted into the first opening part 4B of the board 4, into the second opening part 12A of the FPC 112 and securing to the front case 5. In other words, the first opening part 4B of the board 4 is aligned with and faces the second opening part 12A of the FPC 112, and the securing part 11 secures the FPC 112 so as to clamp the FPC between the front case 5 and the board 4.

As depicted in FIG. 4, the second grounding part 12D and the second conductive part 12B are exposed through the insulating part 12J on the surface of the FPC 112, and as depicted in FIG. 5, the third grounding part 12E is exposed through the insulating part 12J on the back surface of the FPC 112. As depicted in FIG. 6, on the surface of the board 4 facing the front case 5 (hereinafter also referred to as the upper surface), a first grounding part 4C and a first conductive part 4D are provided around the first opening part 4B. The first grounding part 4C and the first conductive part 4A are each composed of a semicircular annular conductive metal so as to surround the periphery of the first opening part 4B.

The first grounding part 4C of the board 4 faces the second grounding part 12D of the FPC 112. The first grounding part 4C is an annular conductive member having a shape similar to that of the second grounding part 12D of the FPC 112. The first grounding part 4C is in contact with the second grounding part 12D and is therefore grounded to the ground electric potential. On the other hand, the first conductive part 4A of the board 4 faces the second conductive part 12B of the FPC 112. The first conductive part 4A is an annular conductive member having a shape substantially similar to that of the second conductive part 12B of the FPC 112. The first conductive part 4A is in contact with the second conductive part 12B and is therefore at a prescribed electric potential, which is the power supply.

On the other hand, on the surface of the board 4 opposite to the upper surface facing the front case 5 (hereinafter also referred to as the lower surface), a conductive annular fourth grounding part 4Z is provided around the first opening part 4B so as to surround the first opening part 4B. The fourth grounding part 4Z is provided to increase the contact area with the securing part 11 and enables reducing the contact resistance with the securing part 11.

According to this configuration, the power supplied via the wire 12P inside the FPC 112 is supplied to the board 4 via the second conductive part 12B and the first conductive part 4A of the FPC 112. On the other hand, the first grounding part 4C of the board 4 is grounded to the ground electric potential via the second grounding part 12D of the FPC 112. The front case 5 is grounded to the ground electric potential via the third grounding part 12E of the FPC 112.

As described above, the camera device 100 as an example of an on-board camera device according to the present embodiment includes a housing that forms a space inside, a board 4 that is provided within the housing and has a prescribed rigidity, and an FPC 112 as an example of a flexible printed circuit board that supplies power from the board 4 positioned within the housing to electronic components positioned outside the housing. The board 4 includes a first conductive part 4A that serves as a power supply and supplies a prescribed electric potential, and a first opening part 4B that penetrates the board 4. The FPC 112 includes a second opening part 12A that penetrates the FPC 112, and a second conductive part 12B that is positioned opposite the first conductive part 4A of the board 4 and has a shape that conforms to the second opening part 12A. The housing has a securing part 11 that is inserted into the first opening part 4B and the second opening part 12A to secure the board 4 to the FPC 112 while bringing the first conductive part 4A into contact with the second conductive part 12B. The securing part 11 is a protrusion extending from the housing. The securing part 11 will be described in detail later.

With the above configuration, the FPC 112 can reliably supply power to the board 4 without using a connector installed on the board 4. Furthermore, by reducing the size of the flexible printed circuit board (for example, the FPC 112) that serves as a terminal connected to the built-in board 4 from the outside, the on-board camera device size can be reduced, and the on-board camera device can be made easier to assemble.

With the present embodiment, the FPC 112 includes a peripheral edge insulating part 12F positioned along the peripheral edge of the second opening part 12A. The second conductive part 12B is positioned a prescribed distance away from the peripheral edge insulating part 12F. This prevents the current from the power supply from flowing to the securing part 11, which is at ground potential, and causing a short circuit.

In the present embodiment, the board 4 further includes a first grounding part 4C that is grounded to a ground potential that is an electric potential relatively lower than the prescribed electric potential. The FPC 112 further includes the second grounding part 12D positioned at a position corresponding to the first grounding part 4C of the board 4. The second grounding part 12D is positioned along the second opening part 12A on the same surface as the second conductive part 12B. In this way, the FPC 112 is reliably connected to the ground electric potential on the board 4 via the second grounding part 12D provided around the securing part 11 without a connector.

In the present embodiment, the FPC 112 includes a third grounding part 12E, which is grounded to ground electric potential, on the rear side of the surface on which the second grounding part 12D is positioned. The third grounding part 12E is positioned along the second opening part 12A. This increases the number of paths through which static electricity flowing through at least one of the front case 5 and the rear case 7, which are examples of a housing, can escape to the outside of the housing.

In the present embodiment, the second conductive part 12B has a semicircular arc shape with a radius larger than the radius of the second opening part 12A. The second grounding part 12D has the same radius as the second conductive part 12B and is a semicircular arc shape that shares a common center with the semicircular arc shape of the second conductive part 12B. In this way, simply by passing the securing part 11 of the housing through the first opening part 4B of the board 4, the second opening part 12A of the FPC 112, the second conductive part 12B and the first conductive part 4A are electrically connected, and the second grounding part 12D and the first grounding part 4C are electrically connected, simplifying positioning of the FPC 112.

In the present embodiment, the FPC 112 includes an isolation insulating part 12C positioned between the second grounding part 12D and the second conductive part 12B. In this manner, for example, a short circuit between the second grounding part 12D and the second conductive part 12B can be prevented.

### Embodiment 2

The camera device as an example of the vehicle-mounted camera device according to Embodiment 2 has almost the same configuration as the camera device 100 according to Embodiment 1, and therefore, a description of the configuration aspects that are the same will be omitted. In Embodiment 2, the description will primarily be differences with Embodiment 1. Embodiment 2 differs from Embodiment 1 mainly in the configuration of the FPC 112, and in the corresponding surrounding configuration aspects that are associated with the difference in the configuration of the FPC 112.

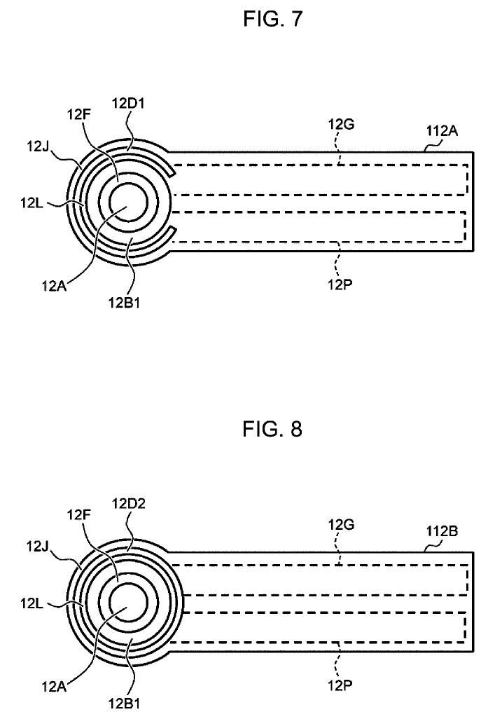

FIG. 7 is a plan view depicting an example of the configuration of an FPC 112A of a camera device according to Embodiment 2. FIG. 7 corresponds to FIG. 4 and FIG. 5 for Embodiment 1. The FPC 112A depicted in FIG. 7 is formed in a single layer so that the ground wire 12G and the power supply wire 12P are on the same layer. Hereinafter, the FPC 112A will also be referred to as the "single-layer FPC 112A".

The single-layer FPC 112A according to Embodiment 2 differs from Embodiment 1 in that a second grounding part 12D1 corresponding to the second grounding part 12D in Embodiment 1 and a second conductive part 12B1 corresponding to the second conductive part 12B in Embodiment 1 are formed on the same surface of the single-layer FPC 112A. The same surface of the single-layer side FPC 112 is the upper surface in the depicted example. That is, in Embodiment 2, the second grounding part 12D1 exposed on the upper surface of the single-layer FPC 112A is connected to the wire 12G, and the second conductive part 12B1 exposed on the upper surface of the single-layer FPC 112A is connected to the wire 12P.

In the present embodiment, as described above, the second conductive part 12B1 has a circular shape with a radius larger than the radius of the second opening part 12A. The second grounding part 12D1 is circular and has a radius larger than the radius of the second conductive part 12B1. In this way, simply by passing the securing part 11 of the housing through the first opening part 4B of the board 4, the second opening part 12A of the FPC 112, the second conductive part 12B and the first conductive part 4A are electrically connected, and the second grounding part 12D and the first grounding part 4C are electrically connected, so the angle of the FPC 112 is not restricted.

The second grounding part 12D1 is formed with an annular peripheral edge insulating part 12F that is formed so as to surround a cylindrical shaped second opening part 12A that is formed along the thickness direction of the single-layer FPC 112A. A second conductive part 12B1 having a similar annular shape is formed on, and so as to surround, the outer periphery of the peripheral edge insulating part 12F. An isolation insulating part 12L having a similar annular shape is formed on, and so as to surround, the outer periphery of the second conductive part 12B1. The second grounding part 12D1 having a partially notched annular shape is formed on, and so as to surround, the outer periphery of the isolation insulating part 12L. A first end of the partially notched portion of the second grounding part 12D1 is connected to the wire 12G. An annular insulating part 12J having a similar annular shape is formed on, and so as to surround, the outer periphery of the second grounding part 12D1.

According to the present embodiment, the second conductive part 12B1 is surrounded by the second grounding part 12D1 or the second grounding part 12D1 that is grounded to the ground electric potential, so that the second conductive part 12B1 is less susceptible to the effects of noise, for example.

### Embodiment 3

The camera device 100B, which is an example of an on-board camera device according to Embodiment 3, has a configuration that is almost identical to the camera device 100 according to Embodiment 1 and the camera device 100A according to Embodiment 2, and therefore a description of configuration aspects that are the same will be omitted. In Embodiment 3, the description will primarily be differences with Embodiment 1 and Embodiment 2. Embodiment 3 differs from Embodiment 1 mainly in the configuration of the FPC 112, and in the corresponding surrounding configuration aspects that are associated with the difference in the configuration of the FPC 112.

FIG. 8 is a plan view depicting an example of the configuration of an FPC 112B of the camera device 100B according to Embodiment 3. FIG. 8 corresponds to FIG. 4 and FIG. 5 in Embodiment 1. The FPC 112B depicted in FIG. 8 is formed as multilayer so that the ground wire 12G and the power supply wire 12P are on different layers. Hereinafter, the FPC 112B will also be referred to as the "multilayer FPC 112B".

The multilayer FPC 112B according to Embodiment 3 differs from Embodiment 1 in that a second grounding part 12D2 corresponding to the second grounding part 12D in Embodiment 1 and a second conductive part 12B1 corresponding to the second conductive part 12B in Embodiment 1 are formed on the same surface of the multilayer FPC 112B. The same surface of the multilayer FPC 112B is the upper surface in the depicted example. That is, in Embodiment 2, the second grounding part 12D2 exposed on the upper surface of the multilayer FPC 112B is connected to the wire 12G, and the second conductive part 12B1 exposed on the upper surface of the multilayer FPC 112B is connected to the wire 12P.

The second grounding part 12D1 is formed with an annular peripheral edge insulating part 12F that is formed so as to surround a cylindrical shaped second opening part 12A that is formed along the thickness direction of the multilayer FPC 112B. A second conductive part 12B1 having a similar annular shape is formed on, and so as to surround, the outer periphery of the peripheral edge insulating part 12F. Although not depicted, a portion of the second conductive part 12B1 is connected to the wire 12P. An isolation insulating part 12L having a similar annular shape is formed on, and so as to surround, the outer periphery of the second conductive part 12B1. A second grounding part 12D2 having a similar annular shape is formed on, and so as to surround, the outer periphery of the isolation insulating part 12L. Although not depicted, a portion of the second grounding part 12D2 is connected to the wire 12G. An insulating part 12J having a similar annular shape is formed on, and so as to surround, the outer periphery of the second grounding part 12D2.

According to the present embodiment, the second conductive part 12B1 is surrounded by the second grounding part 12D1 or the second grounding part 12D2 that is grounded to the ground electric potential, so that the second conductive part 12B1 is less susceptible to the effects of noise, for example.

### Embodiment 4

A camera device 100C, which is an example of an on-board camera device according to Embodiment 4, has a configuration that has nearly the same configuration as the camera devices 100, 100A, and 100B according to the Embodiments 1 to 3, respectively, and therefore a description of configuration aspects that are the same will be omitted. In Embodiment 4, the description will primarily be differences with Embodiments 1 to 3. Embodiment 4 differs from Embodiment 1 mainly in the configuration of the FPC 112, and in the corresponding surrounding configuration aspects that are associated with the difference in the configuration of the FPC 112.

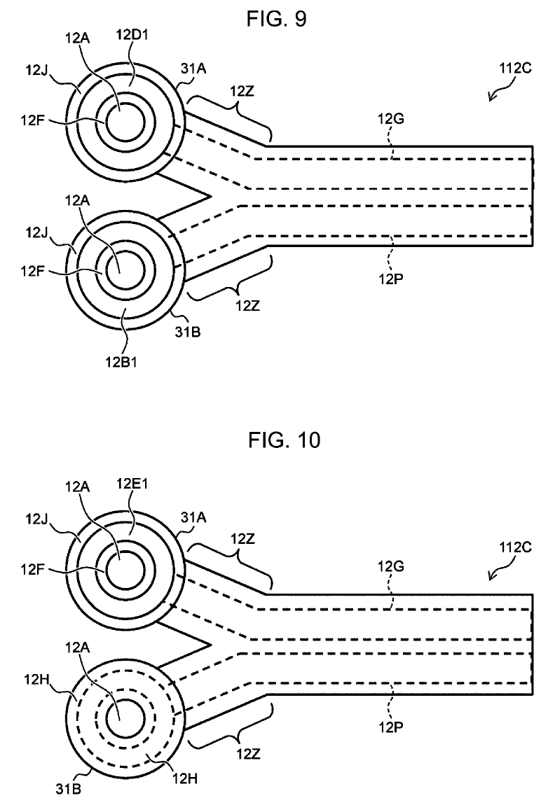

FIG. 9 and FIG. 10 are plan views each depicting an example of the configuration of an FPC 112C of a camera device 100C according to Embodiment 4. FIG. 9 and FIG. 10 correspond to FIG. 4 and FIG. 5 in Embodiment 1, respectively. As will be described later, the FPC 112C is formed so as to be bifurcated into a first annular end part 31A that is continuous with the ground wire 12G and a second annular end part 31B that is continuous with the power supply wire 12P. As depicted in FIG. 9 and FIG. 10, the ground is sometimes referred to as GND and the power supply as Power. FIG. 9 depicts an example of the configuration of the lower surface of the FPC 112C facing the board 4. FIG. 10 depicts an example of the configuration of the upper surface of the FPC 112C that faces the front case 5. In other words, the upper surface depicted in FIG. 10 is the surface opposite to the lower surface depicted in FIG. 9.

In the present embodiment, a first grounding part 4C1, the second grounding part 12D1, a third grounding part 12E1, a first conductive part 4A1, and the second conductive part 12B1 each have different structures, but have substantially the same functions as the first grounding part 4C, the second grounding part 12D, the third grounding part 12E, the first conductive part 4A, and the second conductive part 12B in the Embodiments 1 to 3 described above.

The FPC 112C has a configuration in which a ground wire 12G and a power supply [wire] 12P for ensuring electrical conduction with the heater 101 are wrapped in an insulator. That is, the wire 12G is grounded to ground potential. The wire 12P is connected to a power supply. The FPC 112C has annular end parts 31A and 31B on the side opposite to the end part connected to the heater 101.

In the FPC 112C, the isolation insulating part 12Z branches, for example, in a first direction and a second direction that forms a prescribed angle with the first direction. The second conductive part 12B1 is positioned in the first direction where the isolation insulating part 12Z branches off. The second grounding part 12D1 is positioned in a second direction where the isolation insulating part 12Z branches off.

As depicted in FIG. 9, the front side of the annular end part 31A includes an annular second opening part 12A, a peripheral edge insulating part 12F, a second grounding part 12D1, and an insulating part 12J. The second opening part 12A is a circular hole formed in the center of the annular end part 31A. An annular peripheral edge insulating part 12F is formed around the second opening part 12A.

The second grounding part 12D1 is formed in an annular shape along the periphery of the annular shaped peripheral edge insulating part 12F. The second grounding part 12D1 is connected to the wire 12G. An annular insulating part 12J is formed around the second grounding part 12D1.

The annular end part 31B includes a circular second opening part 12A, a peripheral edge insulating part 12F, a second conductive part 12B1, and an insulating part 12J. The second opening part 12A is a circular hole formed in the center of the annular end part 31A. An annular peripheral edge insulating part 12F is formed around the second opening part 12A. The second conductive part 12B1 is formed on the periphery of, and so as to surround, the peripheral edge insulating part 12F.

The second conductive part 12B1 is formed in an annular shape along the periphery of the peripheral edge insulating part 12F. The second conductive part 12B1 is connected to the wire 12P. An annular insulating part 12J is formed around the second grounding part 12D1.

As depicted in FIG. 10, the back side of the annular end part 31A is provided with a circular second opening part 12A, a peripheral edge insulating part 12F, a third grounding part 12E1, and an insulating part 12J. The second opening part 12A is a circular hole formed in the center of the annular end part 31A. An annular peripheral edge insulating part 12F is formed around the second opening part 12A.

The third grounding part 12E1 is formed in an annular shape along the periphery of the annular shaped peripheral edge insulating part 12F. The third grounding part 12E1 is connected to the wire 12G. An annular insulating part 12J is formed around the third grounding part 12E1.

The annular end part 31B is covered with the insulating part 12H and the isolation insulating part 12Z, and none of the grounding parts are exposed.

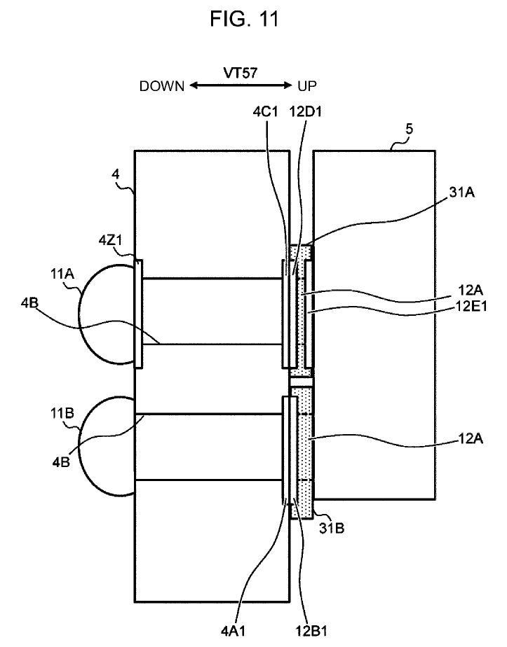

FIG. 11 is a cross-sectional view depicting an example of a configuration in which an FPC 112C is secured between the front case 5 and the board 4 by two securing parts 11A and 11B. In FIG. 11, hatching that should be depicted in the cross-sectional structure is omitted. The following description will be made with reference to FIG. 9 and FIG. 10. The securing parts 11A and 11B have substantially the same functions as the securing part 11 in Embodiments 1 to 3 described above.

The FPC 112C is clamped between the front case 5 and the board 4 and is secured between the front case 5 and the board 4 by inserting the securing part 11, which is inserted into the first opening part 4B of the board 4, into the second opening part 12A of the FPC 112C and securing the securing part to the front case 5. That is, the first opening part 4B of the board 4 is aligned with and faces the second opening part 12A of the FPC 112C, and the securing parts 11A and 11B clamp the FPC 112C between the front case 5 and the board 4 to secure the FPC.

As depicted in FIG. 9, on the surface of the FPC 112C, the second grounding part 12D1 is exposed through the insulating part 12J at the annular end part 31A, and the second conductive part 12B1 is exposed through the insulating part 12J at the annular end part 31B. As depicted in FIG. 10, on the back surface of FPC 112C, the third grounding part 12E1 is exposed through the insulating part 12J at the annular end part 31A, but no conductive part is exposed through the insulating part 12J at the annular end part 31B. In the example depicted in FIG. 11, the annular end part 31A and the annular end part 31B are depicted to be close to each other, but in reality, for example, the annular end part 31A and the annular end part 31B are positioned so that they are physically separated from each other.

As depicted in FIG. 11, on the upper surface of the board 4 facing the front case 5, the first grounding part 4C1 and the first conductive part 4A1 are provided around each first opening part 4B. The first grounding part 4C1 and the first conductive part 4A1 are each composed of a semicircular annular conductive metal so as to surround the periphery of the first opening part 4B.

The first grounding part 4C1 of the board 4 faces the second grounding part 12D1 of the FPC 112C. The first grounding part 4C1 is an annular conductive member having a shape similar to that of the second grounding part 12D1 of the FPC 112C. The first grounding part 4C1 is in contact with the second grounding part 12D1 and is therefore grounded to the ground electric potential. On the other hand, the first conductive part 4A1 of the board 4 faces the second conductive part 12B1 of the FPC 112C. The first conductive part 4A1 is an annular conductive member having a shape substantially similar to that of the second conductive part 12B1 of the FPC 112C. The first conductive part 4A1 is in contact with the second conductive part 12B1 and is therefore at a prescribed electric potential, which is the power supply.

On the other hand, on the lower surface of the board 4 opposite to the upper surface facing the front case 5, a fourth grounding part 4Z1 made of an annular conductive member is provided around the first opening part 4B so as to surround the first opening part 4B. The fourth grounding part 4Z1 is provided to increase the contact area with a securing part 11A and can reduce the contact resistance with the securing part 11A.

According to this configuration, the power supplied via the wire 12P inside the FPC 112C is supplied to the board 4 via the second conductive part 12B1 and the first conductive part 4A1 of the FPC 112C. On the other hand, the first grounding part 4C1 of the board 4 is grounded to the ground electric potential via the second grounding part 12D1 of the FPC 112C. The front case 5 is grounded to the ground electric potential via the third grounding part 12E1 of the FPC 112C.

In the present embodiment, the isolation insulating part 12Z branches in a first direction and a second direction. The second conductive part 12B is positioned in the first direction where the isolation insulating part 12Z branches off. The second grounding part 12D is positioned in a second direction where the isolation insulating part 12Z branches off. In this manner, when the securing part 11 of the housing is passed through the first opening part 4B of the board 4 and the second opening part 12A of the FPC 112, the second conductive part 12B and the first conductive part 4A, as well as the second grounding part 12D and the first grounding part 4C are separated and electrically connected, thereby reducing the possibility of a short circuit.

### Embodiment 5

A camera device 100D, which is an example of an on-board camera device according to Embodiment 5, has a configuration that has nearly the same configuration as the camera devices 100, 100A, 100B, and 100C according to the Embodiments 1 to 4, respectively, and therefore a description of configuration aspects that are the same will be omitted. In Embodiment 4, the description will primarily be differences with Embodiments 1 to 4. Embodiment 5 differs from the Embodiments 1 to 4 in that a positioning mechanism for any one of the FPC 112, FPC 112A, FPC 112B, and FPC 112C is provided. The positioning mechanism for the FPC 112 in Embodiment 1 depicted in FIG. 4 will be illustrated below.

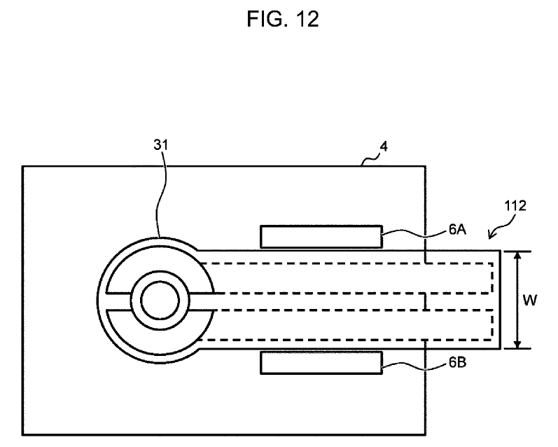

FIG. 12 is a plan view depicting an example of a configuration in which the FPC 112 is positioned and arranged on an upper surface of the board 4. In the depicted example, the configuration of the upper surface of the board 4 is partially omitted.

In the present embodiment, the surface of the board 4 facing at least one of the front case 5 and rear case 7, which is an example of a housing, is provided with a plurality of positioning parts 6A and 6B for securing the position of the FPC 112 by suppressing rotation around the second opening part 12A on the FPC 112. For example, in the present embodiment, the surface facing at least one of the front case 5 and the rear case 7 as an example of a housing is the surface facing the front case 5. With this configuration, positioning of an FPC 112 can be easily performed when assembling a camera device 100 or the like.

In other words, with the present embodiment, positioning parts 6A and 6B that regulate the position of the FPC 112 in the longitudinal direction may be mounted on the surface of the board 4. The distance between the positioning parts 6A and 6B is, for example, a width W that is the same as the FPC 112 in the width direction. Furthermore, the positioning parts 6A and 6B may have a shape extending along the longitudinal direction of the FPC 112. For example, the positioning parts 6A and 6B may be convex parts provided on the surface of the board 4 or may be clips or pogo pins. The height of the positioning parts 6A and 6B is preferably equal to or less than the thickness of the FPC 112. This enables reducing the size of the housing compared to if the connector were provided in the thickness direction of the board 4.

The plurality of positioning parts 6A and 6B are formed on the upper surface of the board 4 at intervals slightly wider than the width W of the FPC 112. The positioning parts 6A and 6B are protruding members provided on the upper surface of the board 4. The FPC 112 is easily positioned in the width W direction using the positioning parts 6A and 6B. The positioning parts 6A and 6B may be replaced by electronic components provided on the upper surface of the board 4. In this manner, a protruding member need not be intentionally provided.

### Modified Example of the Securing Part

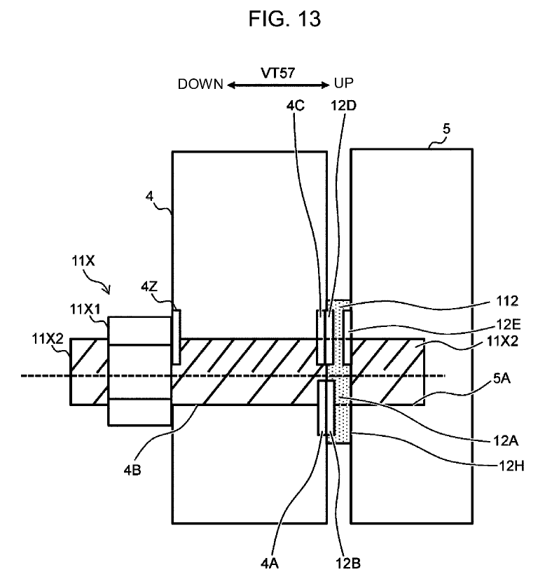

FIG. 13 is a partial cross-sectional view depicting a modified example of a configuration in which a securing part 11X, instead of securing parts 11A and 11B, secures the FPC 112 and the like to the front case 5 by clamping the FPC and the like between the board 4 and the front case 5. The securing part 11 is a name used when the securing parts 11A, 11B, 11X, and 11Y are not distinguished from one another.

The securing part 11X may be a third opening part provided in the housing and a protrusion mated with the third opening part. The securing part 11X may be, for example, a nut 11X1 and a bolt 11X2 as depicted in the drawing, instead of the rivet depicted in the above embodiment. For example, when the securing part 11X is composed of a nut 11X1 and a bolt 11X2, the bolt 11X2 standing up from a third opening part 5A, which is a hole formed in the front case 5, passes through the first opening part 4B of the FPC 112C, and the nut 11X1 is attached to the tip end of the bolt 11X2. The bolt 11X2 is, for example, a rod-shaped member having a spiral groove on the circumferential side surface thereof. The nut 11X1 has, for example, a cylindrical inner peripheral surface on which a spiral groove is formed. A spiral groove formed on the inner peripheral surface of the nut 11X1 engages with a spiral groove formed on the side peripheral surface of the bolt 11X2. The nut 11X1 is attached to a first tip end of the bolt 11X2 by being screwed on while being mated from the first tip end of the bolt 11X2 such that spiral grooves of the nut and spiral grooves of the bolt engage with each other.

The securing part 11X has a third opening part 5A formed in the housing and a bolt 11X2 as an example of a protrusion that is inset into the third opening part 5A. With the configuration described above, the FPC 112 and the like can be reliably secured between the board 4 and the front case 5 by the securing part 11X, and the same effects as each of the embodiments described above can be achieved.

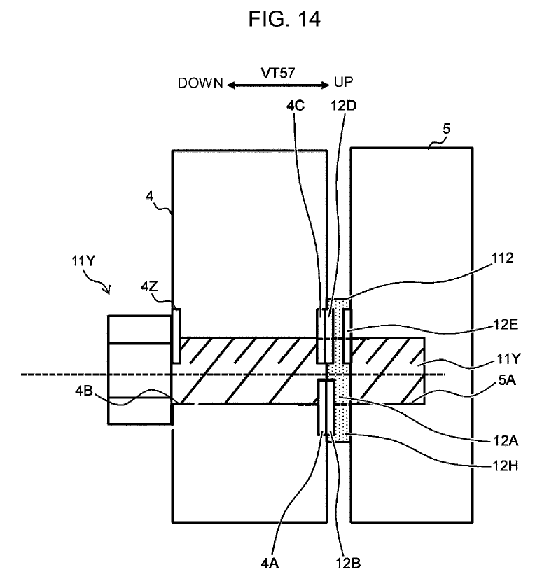

FIG. 14 is a partial cross-sectional view depicting a modified example of the configuration in which the securing part 11Y secures the FPC 112 and the like to the front case 5 by clamping the FPC between the board 4 and the front case 5. The securing part 11Y, in place of the securing parts 11A and 11B, secures the FPC 112 and the like to the front case 5 by clamping the FPC between the board 4 and the front case 5.

The securing part 11Y has a third opening part 5A provided in the housing and a screw as an example of a protrusion that is inset into the third opening part 5A. The screw is, for example, a rod-shaped member, and is a so-called screw having a spiral groove formed on the side circumferential surface of the rod-shaped member. With the configuration described above, the FPC 112 and the like can be reliably secured between the board 4 and the front case 5 by the securing part 11Y, and the same effects as each of the embodiments described above can be achieved.

The present invention is not limited to the abovementioned embodiment and includes various modified examples and equivalent configurations within the purport of the attached Scope of Patent Claims. For example, while the abovementioned embodiment has been described in detail in order to describe the present invention in an easy-to-understand manner, the present invention is not necessarily limited to having all of the configurations described. In addition, each element described in parallel in the present embodiment may be an aspect in which at least one of the elements is connected in series to another element.

Note that the present invention can be applied to devices other than the heater 101. For example, the present invention is widely applicable to electronic components positioned outside the front case 5 and rear case 7 and electrically connected to the board via the FPC 112 inside a device including the front case 5, rear case 7, board 4, and FPC 112.

### DESCRIPTION OF CODES

Camera device main body, 3. Lens barrel, 4. Board, 4A. First conductive part, 4B. First opening part, 4C. First grounding part, 5. Front case, 5A. Third opening part, 6A, 6B. Positioning part, 7. Rear case, 11, 11A, 11B, 11X, 11Y. Securing part, 11X2. Bolt, 12A. Second opening part, 12B, 12B1. Second conductive part, 12C. Peripheral edge insulating part, 12D, 12D1, 12D2. Second grounding part, 12E. Third grounding part, 12L, 12Z. Isolation insulating part, 100. Camera device, 112 to 112C. FPC.

1. An on-board camera device comprising:
a housing that forms an internal space;
a rigid printed circuit board provided in the housing and having prescribed rigidity; and
a flexible printed circuit board that supplies electric power from the rigid printed circuit board positioned in the housing to an electronic component positioned outside the housing,
wherein
the rigid printed circuit board includes:
a first conductive part that supplies a prescribed electric potential serving as a power supply; and
a first opening part that penetrates the rigid printed circuit board,
the flexible printed circuit board includes:
a second opening that penetrates the flexible printed circuit board; and
a second conductive part that is positioned at a position facing the first conductive part of the rigid printed circuit board and has a shape along the second opening part,
the housing includes:
a securing part that is inserted into the first opening part and the second opening part and secures the rigid printed circuit board to the flexible printed circuit board while bringing the first conductive part into contact with the second conductive part; and
the securing part is a protrusion extending from the housing or a third opening part provided on the housing and a protrusion that is mated with the third opening part.

2. The on-board camera device according to claim 1, wherein the flexible printed circuit board includes a peripheral edge insulating part positioned along a peripheral edge of the second opening part, and the second conductive part is positioned at a prescribed distance away from the peripheral edge insulating part.

3. The on-board camera device according to claim 1,
wherein
the rigid printed circuit board further includes a first grounding part that is grounded to a ground potential that has an electric potential relatively lower than the prescribed electric potential,the flexible printed circuit board further includes a second grounding part positioned at a position corresponding to the first grounding part of the rigid printed circuit board, andthe second grounding part is positioned on the same surface as the second conductive part along the second opening part.

4. The on-board camera device according to claim 3, whereinthe flexible printed circuit board includes a third grounding part that is grounded to a ground electric potential and is provided on a rear side of a surface on which the second grounding part is positioned, and
the third grounding part is positioned along the second opening part.

5. The on-board camera device according to claim 3, wherein
the second conductive part has a circular shape having a radius larger than a radius of the second opening part, and
the second grounding part has a circular shape having a radius larger than a radius of the second conductive part.

6. The on-board camera device according to claim 3, wherein
the second conductive part has a semicircular arc shape having a radius larger than a radius of the second opening part, and
the second grounding part has a semicircular arc shape having the same radius as the second conductive part and sharing a center with the semicircular arc shape of the second conductive part.

7. The on-board camera device according to claim 3, wherein the flexible printed circuit board includes an isolation insulating part positioned between the second grounding part and the second conductive part.

8. The on-board camera device according to claim 7, wherein
the isolation insulating part branches in a first direction and a second direction,the second conductive part is positioned in the first direction in which the isolation insulating part branches, andthe second grounding part is positioned in the second direction in which the isolation insulating part branches.

9. The on-board camera device according to claim 1, wherein
a plurality of positioning parts are provided on a surface of the rigid printed circuit board that face the housing, the plurality of positioning parts suppressing rotation of the flexible printed circuit board about the second opening part and securing a position of the flexible printed circuit board.
